(19) United States
(12) Patent Application Publication
(10) Pub. No.: US 2026/0072461 A1
(43) Pub. Date: Mar. 12, 2026

(54) OVERCURRENT PROTECTION INTEGRATED CIRCUIT

(71) Applicants: SANKEN ELECTRIC CO., LTD., Niiza-Shi (JP); SANKEN ELECTRIC KOREA CO.,LTD., Seoul (KR)

(72) Inventors: Koichi ITO, Seoul (KR); KYU SAM CHOI, Seoul (KR); Koichi SHIOTSU, Niiza-Shi (JP)

(21) Appl. No.: 19/324,431

(22) Filed: Sep. 10, 2025

(30) Foreign Application Priority Data
Sep. 11, 2024 (JP) 2024-157759

(51) Int. Cl. G05F 1/573; G05F 1/575; H10D 1/47; H10D 80/20

(52) U.S. Cl. CPC G05F 1/573; G05F 1/575; H10D 1/474; H10D 80/213

(57) ABSTRACT

An overcurrent protection integrated circuit includes: a current input including a first resistor receiving an input current; a current sense amplifier circuitry including a differential amplifier, a switching element, a second resistor, and a current mirror circuit; and an overcurrent determiner including a third resistor and an overcurrent protection comparator. The current sense amplifier circuitry controls, through the differential amplifier, a voltage of the second resistor to be equal to a voltage of the first resistor, and sends out, from the switching element toward the current mirror circuit, a current decreased to a predetermined ratio relative to the input current. The overcurrent determiner compares a voltage of the third resistor and a voltage of a direct-current power supply, and outputs a signal when the voltage of the third resistor exceeds the voltage of the direct-current power supply. The first resistor and the second resistor include the same metal material.

### CROSS-REFERENCE TO RELATED APPLICATIONS

This application claims priority from Japanese Patent Application No. 2024-157759 filed on Sep. 11, 2024, the entire contents of which are hereby incorporated by reference.

### BACKGROUND

The disclosure relates to an overcurrent protection integrated circuit couplable to a constant voltage direct-current power supply.

Some of existing integrated circuit devices manufactured as semiconductor chips are provided with a current detection resistor and used to configure a current detection circuit within a semiconductor circuit. Regarding the current detection resistor, there is an issue that a resistance value thereof changes with a rise in temperature of the integrated circuit device. To address this, techniques have been proposed to prevent a change in resistance value along with a change in temperature from affecting other components.

For example, according to Japanese Patent No. 3239052, a metal wiring including a metal material is provided in a part of a semiconductor integrated circuit, and is used to configure a current detection part. The metal wiring is routed from one device to another device in the semiconductor integrated circuit to thereby electrically couple the devices to each other. The metal wiring includes a highly conductive metal material, such as aluminum, copper, or gold.

Japanese Patent No. 3239052 discloses a technique to allow a temperature characteristic of a current detection resistor configured by the metal wiring in the current detection part and a temperature characteristic of a voltage control circuit to match each other to thereby cancel out a variation in a detected current value caused by a change in temperature.

Japanese Unexamined Patent Application Publication (JP-A) No. 2002-026707 relates to an overcurrent protection device for a metal-oxide semiconductor (MOS) transistor. JP-A No. 2002-026707 discloses a technique in which, regarding an on-resistance of the MOS transistor, a ratio R1/R2 of a resistance value of a resistor R1 coupled to a comparator to a resistance value of a resistor R2 coupled to an operational amplifier is set to a suitable value to lessen an effect of a change in temperature, and to thereby cancel out a variation in a detected current value caused by a change in temperature.

JP-A No. 2007-236126 relates to a power system and an electronic apparatus employing the power system. JP-A No. 2007-236126 discloses a technique in which a metal resistor serving as a current detection resistor and a transistor operating in a saturation region are coupled in series to each other and an effect of a rise in temperature on a voltage value of the metal resistor is canceled out through a rise in resistance value of the metal resistor in response to the rise in temperature and a resulting decrease in current flowing through the transistor.

### SUMMARY

An overcurrent protection integrated circuit according to one or more embodiments may be couplable to a constant voltage direct-current power supply. The overcurrent protection integrated circuit may include a current input, a current sense amplifier circuitry, and an overcurrent determiner. The current input may includes a first resistor configured to receive an input current. The current sense amplifier circuitry includes a differential amplifier, a switching element, a second resistor, and a current mirror circuit. The overcurrent determiner includes a third resistor and an overcurrent protection comparator. The differential amplifier includes a first input, a second input, and an output. The first input is coupled to a part of the current input on a current-sending side. The second input is coupled to the second resistor. The switching element is coupled to the second resistor and the output. The current mirror circuit includes a first active element and a second active element. The first active element is coupled to the switching element. The second active element is coupled to the third resistor. The overcurrent protection comparator includes a first determination input, and a second determination input. The first determination input is coupled to the second active element. The second determination input is couplable to the constant voltage direct-current power supply. The current sense amplifier circuitry is configured to control, through the differential amplifier, a voltage of the second resistor to be equal to a voltage of the first resistor, and configured to send out, from the switching element toward the current mirror circuit, a current decreased to a predetermined ratio relative to the input current. The overcurrent determiner is configured to compare a voltage of the third resistor and a voltage of the constant voltage direct-current power supply, and to output a signal when the voltage of the third resistor exceeds the voltage of the constant voltage direct-current power supply. The first resistor and the second resistor each include a metal material. The metal material that the first resistor includes and the metal material that the second resistor includes are the same as each other.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a diagram schematically illustrating a circuit configuration of an overcurrent protection integrated circuit according to one embodiment of the disclosure.

FIG. 2 is an explanatory diagram illustrating the circuit configuration of the overcurrent protection integrated circuit of FIG. 1 including resistance values resulting from a temperature rise of each of a first resistor and a second resistor to 100° C.

FIGS. 3A, 3B, and 3C are explanatory diagrams schematically illustrating examples of close positioning of the first resistor and the second resistor in respective different semiconductor circuit formation layers, FIG. 3A illustrating an example in which the first resistor and the second resistor overlap each other vertically, FIG. 3B illustrating an example in which respective portions of the first resistor and the second resistor overlap each other vertically, FIG. 3C illustrating an example in which the first resistor and the second resistor are close to each other in a direction along a plane of the semiconductor circuit formation layers.

FIGS. 4A and 4B are explanatory diagrams illustrating example shapes of the second resistor, FIG. 4A illustrating an example in which the second resistor has a linear shape, FIG. 4B illustrating an example in which the second resistor has a linear shape and is folded back once.

FIG. 5 is an explanatory diagram illustrating the second resistor provided to span two semiconductor circuit formation layers via interlayer conductive members.

FIG. 6 is an explanatory diagram illustrating an example in which a dummy pattern is provided close to the second resistor.

FIG. 7 is an explanatory diagram illustrating an example of a defective second resistor that is nonuniform in width in a lateral direction.

### DETAILED DESCRIPTION

Japanese Patent No. 3239052 proposes to allow a temperature characteristic of a current detection resistor configured by a metal wiring and a temperature characteristic of a voltage control circuit to match each other. However, a manufacturing error can occur for each of the metal wiring and the voltage control circuit, and it is therefore difficult to eliminate a difference between their respective temperature characteristics resulting from the manufacturing error.

JP-A No. 2002-026707 proposes to set a ratio R1/R2 of a resistance value of a resistor R1 coupled to a comparator to a resistance value of a resistor R2 coupled to an operational amplifier to a suitable value in a circuit of an overcurrent protection device to thereby cancel out a variation in current value caused by a change in temperature. However, a manufacturing error can occur for each of the resistors R1 and R2, and it is therefore difficult to eliminate a difference between their respective temperature characteristics resulting from the manufacturing error.

JP-A No. 2007-236126 proposes to serially couple a metal resistor and a transistor in a power system and an electronic apparatus employing the power system to thereby cancel out an effect of a rise in temperature on a voltage value of the metal resistor. However, a manufacturing error can occur for each of a metal resistor and a transistor, and it is therefore difficult to eliminate a difference between their respective temperature characteristics resulting from the manufacturing error.

It may be desirable to provide an overcurrent protection integrated circuit that makes it possible to cancel out an effect of a change in temperature without being affected by a manufacturing error.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same reference numerals to avoid any redundant description. In addition, elements that are not directly related to any embodiment of the disclosure are unillustrated in the drawings.

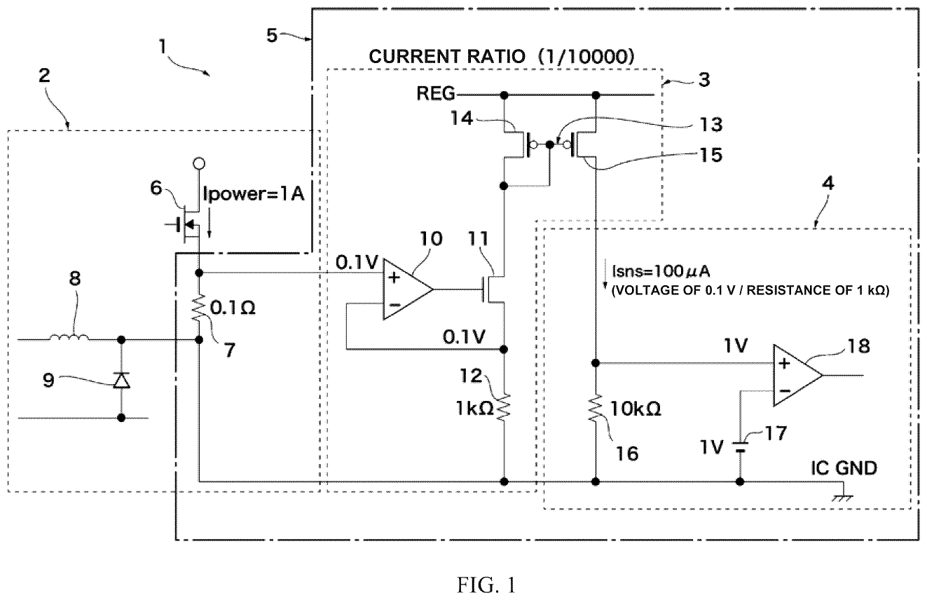

FIG. 1 schematically illustrates a circuit configuration of an overcurrent protection integrated circuit 1 according to an example embodiment of the disclosure. The overcurrent protection integrated circuit 1 may be incorporated in a non-insulated chopper, and includes a current input 2, a current sense amplifier circuitry 3, and an overcurrent determiner 4.

A part of the overcurrent protection integrated circuit 1 may be fabricated as an integrated circuit 5 (see FIG. 1). The integrated circuit 5 may be a microwave integrated circuit (MIC).

### Current Input

The current input 2 includes a first resistor 7 configured to receive an input current. The current input 2 may further include a switching element 6, a coil 8, and a rectification diode 9. The switching element 6 may include a metal-oxide-semiconductor field-effect transistor (MOSFET). In the current input 2, the first resistor 7 may be coupled to the switching element 6. The coil 8 and the rectification diode 9 may be coupled to the first resistor 7. In FIG. 1, the input current is represented by an arrow labeled “Ipower”. As a result of the first resistor 7 receiving the input current Ipower from the switching element 6, a voltage may be generated at an end of the first resistor 7. The end of the first resistor 7 may be coupled to the current sense amplifier circuitry 3 to allow a current to flow from the first resistor 7 to the current sense amplifier circuitry 3.

### Current Sense Amplifier Circuitry

In one example, a current flowing through the integrated circuit 5 included in the overcurrent protection integrated circuit 1 may be made as low as possible in current value.

The current sense amplifier circuitry 3 may output a current with its current value decreased to a predetermined ratio relative to the current value of the current from the current input 2. In the overcurrent protection integrated circuit 1 illustrated in FIG. 1, the current sense amplifier circuitry 3 may set a current ratio to 1/10000. The current ratio at the current sense amplifier circuitry 3 may be defined as a current value of a current out of a later-described active element 14 divided by the current value of the current Ipower into the current input 2.

The current sense amplifier circuitry 3 includes a differential amplifier 10, an amplifying element 11, a second resistor 12, and a current mirror circuit 13. Here, the amplifying element 11 may correspond to a specific but non-limiting example of a “switching element”in one embodiment of the disclosure.

As illustrated in FIG. 1, the differential amplifier 10 includes two inputs and an output. Hereinafter, one of the two inputs that is on a positive side will be referred to as a first input, and another of the two inputs that is on a negative side will be referred to as a second input. A part of the current input 2 between the switching element 6 and the first resistor 7, that is, a part of the current input 2 on a current-sending side, may be coupled to the first input (on the positive side) of the differential amplifier 10.

The amplifying element 11 may be coupled to the output of the differential amplifier 10. An end of the second resistor 12 may be coupled to the second input (on the negative side) of the differential amplifier 10 and to the amplifying element 11.

The current mirror circuit 13 includes two active elements 14 and 15. Here, the active element 14 may correspond to a specific but non-limiting example of a “first active element” in one embodiment of the disclosure, and the active element 15 may correspond to a specific but non-limiting example of a “second active element” in one embodiment of the disclosure. The active element 14 is coupled to the amplifying element 11. A current out of the active element 14 may enter a drain of the amplifying element 11.

The current mirror circuit 13 may operate to reference a current value of the current out of the active element 14, and to allow a current having the same current value to be sent out of the active element 15. A reference sign “REG” in the drawings represents a regulator.

The differential amplifier 10 may control a voltage of the second resistor 12 to a voltage value equal to that of the voltage of the first resistor 7. The differential amplifier 10 may cause a current to flow into the active element 14 of the current mirror circuit 13, with its current value decreased to a predetermined ratio (i.e., to the current ratio of 1/10000) relative to the current value of the current from the current input 2.

### Overcurrent Determiner

The overcurrent determiner 4 includes a third resistor 16 and an overcurrent protection comparator 18. The overcurrent determiner 4 may further include a direct-current reference power input 17. Hereinafter, the direct-current reference power input 17 will be referred to as a direct-current reference power supply 17.

The active element 15 of the current mirror circuit 13 is coupled to the third resistor 16. The third resistor 16 may receive a current outputted from the active element 15. In the drawings, the current outputted from the active element 15 is represented by an arrow labeled Isns.

The overcurrent protection comparator 18 includes two determination inputs. Hereinafter, one of the two determination inputs that is on the positive side will be referred to as a first determination input, and another of the two determination inputs that is on the negative side will be referred to as a second determination input. The overcurrent protection comparator 18 may detect a voltage received at the first determination input (on the positive side) and a voltage received at the second determination input (on the negative side), and make a comparison between their voltage values. The voltage received at the first determination input may be a voltage generated at an end of the third resistor 16 as a result of the third resistor 16 receiving the current Isns. The voltage received at the second determination input may be a voltage of the direct-current reference power supply 17.

In the overcurrent protection comparator 18, the first determination input may be coupled to the third resistor 16 to allow the voltage at the end of the third resistor 16 to be received at the first determination input.

In the overcurrent protection comparator 18, the second determination input may be coupled to the direct-current reference power supply 17 to allow a constant voltage from the direct-current reference power supply 17 to be received at the second determination input.

In the example embodiment illustrated in FIG. 1, the voltage of the direct-current reference power supply 17 may be set to 1 V. The overcurrent protection comparator 18 may detect a voltage resulting from a current-to-voltage conversion of the current Isns at the third resistor 16 and the voltage of the direct-current reference power supply 17, and make a comparison between their voltage values.

When the voltage value of the third resistor 16 exceeds the voltage value of the direct-current reference power supply 17, the overcurrent protection comparator 18 outputs an overcurrent protection signal.

Thus, the overcurrent protection integrated circuit 1 may allow no overcurrent protection signal to be sent out when the current into the current input 2 is less than, for example, 1 ampere (1 A), and may allow the overcurrent protection signal to be sent out when the current into the current input 2 becomes equal to 1 A.

In the overcurrent protection integrated circuit 1 according to the example embodiment, the first resistor 7 of the current input 2 and the second resistor 12 of the current sense amplifier circuitry 3 each include a metal material. The metal material that the first resistor 7 includes and the metal material that the second resistor 12 includes are the same as each other. In the example embodiment, the metal material may be aluminum.

In the example embodiment, the first resistor 7 and the second resistor 12 may be metal wiring resistors each including aluminum, as described above. The first resistor 7 and the second resistor 12 may each have a temperature characteristic that brings about a 30% or more increase in resistance value upon a 100° C. increase in temperature.

The first resistor 7 may have a resistance value of 0.1Ω at a temperature of 0° C., and a resistance value of 0.13Ω at a temperature of 100° C. The second resistor 12 may have a resistance value of 1 kΩ at a temperature of 0° C., and a resistance value of 1.3 kΩ at a temperature of 100° C.

### When First Resistor 7 and Second Resistor 12 are 0° C. in Temperature

When the input current Ipower received at the current input 2 is 1 A and the temperature of each of the first resistor 7 and the second resistor 12 is 0° C., the resistance value of the first resistor 7 may be 0.1 Ω and a voltage value of the voltage generated at the end of the first resistor 7 may be 0.1 V, as illustrated in FIG. 1.

The differential amplifier 10 may operate to adjust a voltage value of a voltage generated at an end of the second resistor 12 to 0.1 V. The differential amplifier 10 may operate to send a current with a current value set to 100 μA (=voltage of 0.1 V/resistance of 1 kΩ) from the differential amplifier 10 to the current mirror circuit 13, and to send a current having the current value of 100 μA from the current mirror circuit 13 to the overcurrent determiner 4.

The third resistor 16 in the overcurrent determiner 4 may have a resistance value of 10 kΩ. The current flowing from the current mirror circuit 13 may be received at the third resistor 16. The voltage generated at the end of the third resistor 16 may have a voltage value of 1 V (=current of 100 μA×resistance of 10 kΩ).

Under the presence of the voltage at the end of the third resistor 16, the current Isns from the current mirror circuit 13 may flow through the third resistor 16. Here, the current flowing through the third resistor 13 may be converted into a voltage at the third resistor 16. The voltage resulting from the conversion of the current at the third resistor 16 may be received at the first determination input (on the positive side) of the overcurrent protection comparator 18.

The overcurrent protection comparator 18 may detect the voltage of the third resistor 16 received at the first determination input, and may send out the overcurrent protection signal when the detected voltage is higher in voltage value than the voltage of the direct-current reference power supply 17. The voltage of the third resistor 16 received at the first determination input may be the voltage generated at the end of the third resistor 16 as a result of the third resistor 16 receiving the current Isns.

### When First Resistor 7 and Second Resistor 12 are 100° C. in Temperature

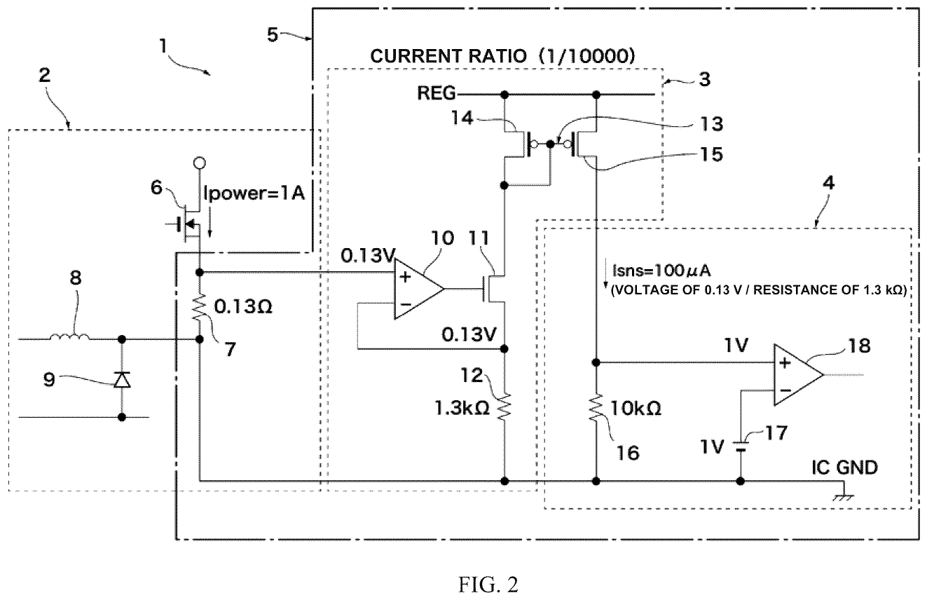

When the input current Ipower received at the current input 2 is 1 A and the temperature of each of the first resistor 7 and the second resistor 12 rises to 100° C., the resistance values of the first resistor 7 and the second resistor 12 may change as illustrated in FIG. 2, due to the temperature characteristics of the first resistor 7 and the second resistor 12.

The resistance value of the first resistor 7 may change to 0.13 Ω. The voltage value of the voltage generated at the end of the first resistor 7 may change to 0.13 V.

The resistance value of the second resistor 12 may change to 1.3 kΩ. The differential amplifier 10 may operate to adjust the voltage value of the voltage generated at the end of the second resistor 12 to 0.13 V.

The differential amplifier 10 may operate to send a current with a current value set to 100 μA (=voltage of 0.13 V/resistance of 1.3 kΩ) from the differential amplifier 10 to the current mirror circuit 13, and to send a current having the current value of 100 μA from the current mirror circuit 13 to the overcurrent determiner 4.

The current flowing from the current mirror circuit 13 may be received at the third resistor 16. The voltage generated at the end of the third resistor 16 may have a voltage value of 1 V (=current of 100 μA×resistance of 10 kΩ).

Under the presence of the voltage at the end of the third resistor 16, the current Isns from the current mirror circuit 13 may flow through the third resistor 16. Here, the current flowing through the third resistor 13 may be converted into a voltage at the third resistor 16. The voltage resulting from the conversion of the current at the third resistor 16 may be received at the first determination input (on the positive side) of the overcurrent protection comparator 18.

The overcurrent protection comparator 18 may detect the voltage of the third resistor 16 received at the first determination input, and may send out the overcurrent protection signal when the detected voltage is higher in voltage value than the voltage of the direct-current reference power supply 17.

The overcurrent protection integrated circuit 1 may include a semiconductor chip including a stack of multiple semiconductor circuit formation layers. The first resistor 7 and the second resistor 12 do not necessarily have to be provided in one semiconductor circuit formation layer.

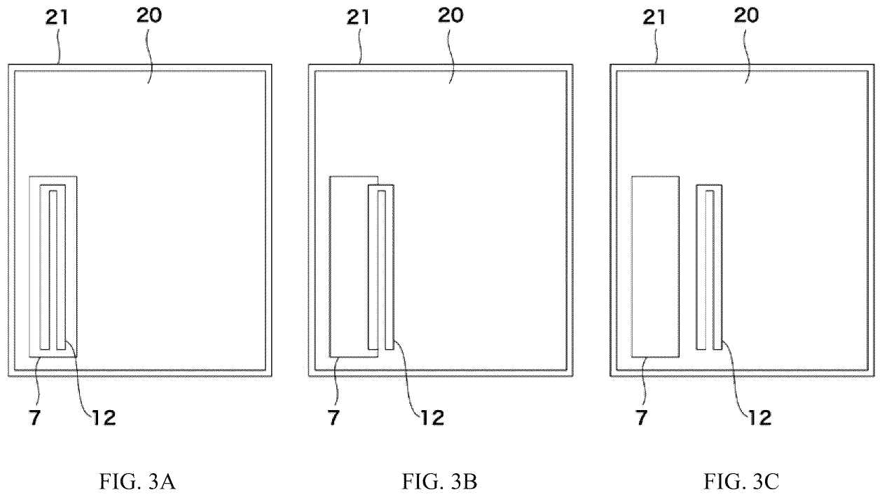

FIGS. 3A, 3B, and 3C each illustrate an example in which the first resistor 7 and the second resistor 12 are provided in different semiconductor circuit formation layers 20 and 21, respectively, and the semiconductor circuit formation layers 20 and 21 are stacked on each other.

In one example, as illustrated in FIG. 3A, the first resistor 7 and the second resistor 12 may be positioned to overlap each other vertically.

In one example, as illustrated in FIG. 3B, the first resistor 7 and the second resistor 12 may be so positioned that respective portions thereof overlap each other vertically.

In one example, as illustrated in FIG. 3C, the first resistor 7 and the second resistor 12 may be positioned close to each other in a direction along a plane of the semiconductor circuit formation layers 20 and 21, that is, in a direction orthogonal to a thickness direction.

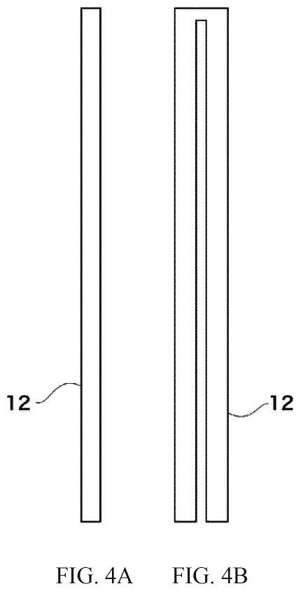

FIGS. 4A and 4B each illustrate an example shape of the second resistor 12. In one example, as illustrated in FIG. 4A, the second resistor 12 may have a linear shape. In one example, as illustrated in FIG. 4B, the second resistor 12 may have a linear shape and be folded back once.

As described above, the second resistor 12 may have a linear shape. As used herein, the “linear shape” is not limited to a single straight-line shape. The term “linear shape” may encompass a long shape with a small number of times of folding back, as illustrated in FIG. 4B.

Increasing the number of times of folding back the second resistor 12 in fabricating the second resistor 12 can generate an inductance component in the resulting second resistor 12. In addition, there is a concern about occurrence of noise.

In some embodiments, the second resistor 12 may be provided only in a single semiconductor circuit formation layer, such as the semiconductor circuit formation layer 21.

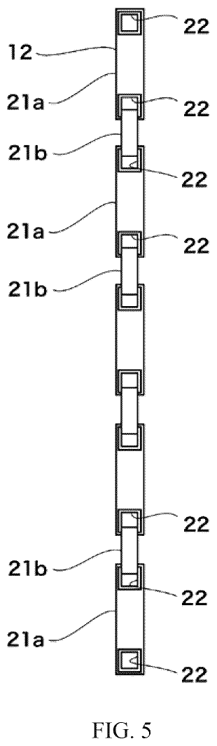

FIG. 5 illustrates an example of the second resistor 12 including a metal wiring 21a and a metal wiring 21b, the metal wiring 21a being provided in the semiconductor circuit formation layer 21, the metal wiring 21b being provided in another semiconductor circuit formation layer stacked on the semiconductor circuit formation layer 21, the metal wirings 21a and 21b being coupled in series to each other through an interlayer conductive member (a via) 22.

Fabricating the second resistor 12 with use of the interlayer conductive member 22 may result in contact resistance in the second resistor 12, which can cause the second resistor 12 to have a resistance value different from a set value. To avoid this, the second resistor 12 may not be provided to span multiple layers.

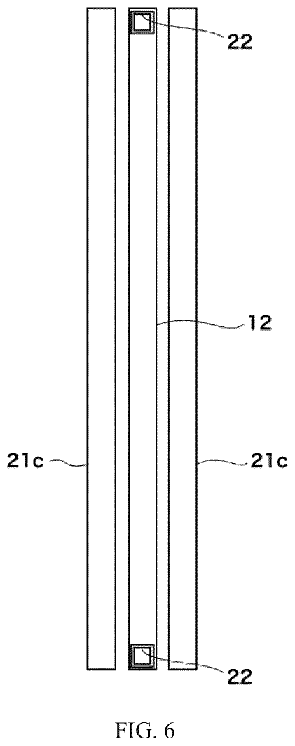

FIG. 6 illustrates an example in which a metal wiring 21c having a linear shape is provided in the vicinity of each of two side parts, of the second resistor 12, extending along a longitudinal direction. The metal wiring 21c may include a metal material the same as the metal material that the second resistor 12 includes.

The metal wiring 21c described above may be provided simultaneously with formation of the second resistor 12. This helps to achieve better reproducibility of the linear shape of the second resistor 12, thus helping to allow easy formation of the second resistor 12.

The metal wiring 21c may include a dummy pattern. The metal wiring 21c as the dummy pattern may not be coupled to any circuit in the semiconductor chip constituting the overcurrent protection integrated circuit 1. In the example illustrated in FIG. 6, the interlayer conductive member 22 may be provided at each end of the second resistor 12.

In some embodiments, the second resistor 12 may be uniform in width in a lateral direction orthogonal to the longitudinal direction.

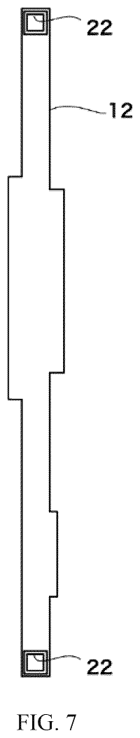

FIG. 7 illustrates an example in which the second resistor 12 is nonuniform in width in the lateral direction. The second resistor 12 having a nonuniform width in the lateral direction can be susceptible to processing variations in resistance value.

In the example embodiment, the metal material included in each of the first resistor 7 and the second resistor 12 may include aluminum. The metal material does not necessarily have to include high purity aluminum. In some embodiments, the metal material may include an aluminum-based alloy.

In the example embodiment, the metal material included in the metal wiring 21c as the dummy pattern may also include aluminum but does not necessarily have to include high purity aluminum. In some embodiments, the metal material may include an aluminum-based alloy.

In any embodiment of the disclosure, the metal material included in each of the first resistor 7 and the second resistor 12 is not limited to aluminum and an aluminum-based alloy.

### Example Effects

As described above, an overcurrent protection integrated circuit according to an embodiment of the disclosure is couplable to a constant voltage direct-current power supply. The overcurrent protection integrated circuit includes a current input, a current sense amplifier circuitry, and an overcurrent determiner. The current input includes a first resistor configured to receive an input current. The current sense amplifier circuitry includes a differential amplifier, a switching element, a second resistor, and a current mirror circuit. The overcurrent determiner includes a third resistor and an overcurrent protection comparator. The differential amplifier includes two inputs and an output. A first one of the two inputs is coupled to a part of the current input on a current-sending side. A second one of the two inputs is coupled to the second resistor. The switching element is coupled to the second resistor and the output. The current mirror circuit includes a first active element and a second active element. The first active element is coupled to the switching element. The second active element is coupled to the third resistor. The overcurrent protection comparator includes two determination inputs. A first one of the two determination inputs is coupled to the second active element. A second one of the two determination inputs is couplable to the constant voltage direct-current power supply. The current sense amplifier circuitry is configured to control, through the differential amplifier, a voltage of the second resistor to be equal to a voltage of the first resistor, and configured to send out, from the switching element toward the current mirror circuit, a current decreased to a predetermined ratio relative to the input current. The overcurrent determiner is configured to compare a voltage of the third resistor and a voltage of the constant voltage direct-current power supply, and to output a signal when the voltage of the third resistor exceeds the voltage of the constant voltage direct-current power supply. The first resistor and the second resistor each include a metal material. The metal material that the first resistor includes and the metal material that the second resistor includes are the same as each other. According to the above-described embodiment of the disclosure, the use of the same metal material for the first resistor of the current input and the second resistor of the current sense amplifier circuitry helps to allow each of the first and second resistors to be free from a manufacturing error in relation to the material. Accordingly, the above-described embodiment of the disclosure helps to prevent the occurrence of a manufacturing error of each of the first resistor of the current input and the second resistor of the current sense amplifier circuitry, and to cancel out an effect of a change in temperature.

In some embodiments, the metal material that the first resistor includes and the metal material that the second resistor includes may include aluminum, or may include an aluminum-based alloy. This helps to allow each of the first and second resistors to be free from a manufacturing error in relation to the material. Accordingly, such embodiments of the disclosure help to prevent the occurrence of a manufacturing error of each of the first resistor of the current input and the second resistor of the current sense amplifier circuitry, and to cancel out an effect of a change in temperature.

In some embodiments, the overcurrent protection integrated circuit may include a semiconductor chip including a stack of multiple semiconductor circuit formation layers. In such a case, the first resistor and the second resistor may be provided in respective different ones of the semiconductor circuit formation layers. Here, the first resistor and the second resistor may be positioned to overlap each other vertically in a thickness direction of the semiconductor circuit formation layers, or positioned close to each other in a direction along a plane of the semiconductor circuit formation layers. Providing the first resistor of the current input and the second resistor of the current sense amplifier circuitry in such positioning helps to make it easy for the first resistor and the second resistor to be equal in temperature.

In some embodiments, the second resistor may have a linear shape. This helps to make it easy to form the second resistor.

In some embodiments, the second resistor may be provided only in one of the multiple semiconductor circuit formation layers. Providing the second resistor to span the multiple semiconductor circuit formation layers would involve an interlayer conductive member to be interposed between the multiple semiconductor circuit formation layers, which would result in contact resistance between the metal material included in the second resistor and the interlayer conductive member. Providing the second resistor with the interposition of the interlayer conductive member thus makes it difficult for the second resistor to exhibit a preset resistance value. In contrast, providing the second resistor only in one of the semiconductor circuit formation layers helps to make it easy for the second resistor to exhibit a preset resistance value.

In some embodiments, the second resistor may be elongated in a longitudinal direction. In such a case, the overcurrent protection integrated circuit may further include a metal wiring provided in the vicinity of a side part, of the second resistor, extending along the longitudinal direction. The metal wiring may have a linear shape and include a metal material the same as the metal material that the second resistor includes. Here, the metal wiring may include a dummy pattern. This helps to allow the side part of the second resistor along the longitudinal direction to be reproducible into a shape as designed, which also helps to make it easy for the second resistor to exhibit a preset resistance value.

Some example embodiments have been described in detail above. However, the above-described embodiments are to facilitate understanding of the disclosure, and are not intended to limit the disclosure. Each element disclosed in the foregoing example embodiments shall thus be construed to include all design modifications and equivalents that fall within the technical scope of the disclosure.

One or more embodiments of the disclosure may have any of the following configurations.
(1) An overcurrent protection integrated circuit couplable to a constant voltage direct-current power supply, the overcurrent protection integrated circuit including:
   a current input including a first resistor configured to receive an input current;
   a current sense amplifier circuitry including a differential amplifier, a switching element, a second resistor, and a current mirror circuit; and
   an overcurrent determiner including a third resistor and an overcurrent protection comparator, in which
   the differential amplifier includes a first input, a second input, and an output, the first input being coupled to a part of the current input on a current-sending side, the second input being coupled to the second resistor,
   the switching element is coupled to the second resistor and the output,
   the current mirror circuit includes a first active element and a second active element, the first active element being coupled to the switching element, the second active element being coupled to the third resistor,
   the overcurrent protection comparator includes a first determination input, and a second determination input, the first determination input being coupled to the second active element, the second determination input being couplable to the constant voltage direct-current power supply,
   the current sense amplifier circuitry is configured to control, through the differential amplifier, a voltage of the second resistor to be equal to a voltage of the first resistor, and configured to send out, from the switching element toward the current mirror circuit, a current decreased to a predetermined ratio relative to the input current,
   the overcurrent determiner is configured to compare a voltage of the third resistor and a voltage of the constant voltage direct-current power supply, and to output a signal when the voltage of the third resistor exceeds the voltage of the constant voltage direct-current power supply, and
   the first resistor and the second resistor each include a metal material, the metal material that the first resistor includes and the metal material that the second resistor includes being the same as each other.
(2) The overcurrent protection integrated circuit according to (1), in which the metal material that the first resistor includes and the metal material that the second resistor includes include aluminum or include an aluminum-based alloy.
(3) The overcurrent protection integrated circuit according to (1), in which
   the overcurrent protection integrated circuit includes a semiconductor chip including a stack of multiple semiconductor circuit formation layers,
   the first resistor and the second resistor are provided in respective different ones of the semiconductor circuit formation layers, and
   the first resistor and the second resistor are positioned to overlap each other vertically in a thickness direction of the semiconductor circuit formation layers, or positioned close to each other in a direction along a plane of the semiconductor circuit formation layers.
(4) The overcurrent protection integrated circuit according to (1), in which the second resistor has a linear shape.
(5) The overcurrent protection integrated circuit according to (3) or (4), in which the second resistor is provided only in one of the semiconductor circuit formation layers.
(6) The overcurrent protection integrated circuit according to (1), in which
   the second resistor is elongated in a longitudinal direction,
   the overcurrent protection integrated circuit further includes a metal wiring provided in the vicinity of a side part, of the second resistor, extending along the longitudinal direction, the metal wiring having a linear shape and including a metal material the same as the metal material that the second resistor includes, and
   the metal wiring includes a dummy pattern.

An overcurrent protection integrated circuit according to at least one embodiment of the disclosure may make it possible to cancel out an effect of a change in temperature without being affected by a manufacturing error.

Although the disclosure has been described hereinabove in terms of the example embodiment and modification examples, the disclosure is not limited thereto. It should be appreciated that variations may be made in the described example embodiment and modification examples by those skilled in the art without departing from the scope of the disclosure as defined by the following claims. The limitations in the claims are to be interpreted broadly based on the language employed in the claims and not limited to examples described in this specification or during the prosecution of the application, and the examples are to be construed as non-exclusive. The use of the terms first, second, etc. do not denote any order or importance, but rather the terms first, second, etc. are used to distinguish one element from another. The term “substantially” and its variants are defined as being largely but not necessarily wholly what is specified as understood by one of ordinary skill in the art. The term “disposed on/provided on/formed on” and its variants as used herein refer to elements disposed directly in contact with each other or indirectly by having intervening structures therebetween. Moreover, no element or component in this disclosure is intended to be dedicated to the public regardless of whether the element or component is explicitly recited in the following claims.

1. An overcurrent protection integrated circuit couplable to a constant voltage direct-current power supply, the overcurrent protection integrated circuit comprising:
a current input comprising a first resistor that receives an input current;
a current sense amplifier circuitry comprising a differential amplifier, a switching element, a second resistor, and a current mirror circuit; and
an overcurrent determiner comprising a third resistor and an overcurrent protection comparator, wherein the differential amplifier comprises a first input, a second input, and an output, the first input being coupled to a part of the current input on a current-sending side, the second input being coupled to the second resistor,
the switching element is coupled to the second resistor and the output,
the current mirror circuit comprises a first active element and a second active element, the first active element being coupled to the switching element, the second active element being coupled to the third resistor,
the overcurrent protection comparator comprises a first determination input, and a second determination input, the first determination input being coupled to the second active element, the second determination input being couplable to the constant voltage direct-current power supply,
the current sense amplifier circuitry controls, through the differential amplifier, a voltage of the second resistor to be equal to a voltage of the first resistor, and sends out, from the switching element toward the current mirror circuit, a current decreased to a predetermined ratio relative to the input current,
the overcurrent determiner compares a voltage of the third resistor and a voltage of the constant voltage direct-current power supply, and outputs a signal in response to the voltage of the third resistor exceeding the voltage of the constant voltage direct-current power supply, and
the first resistor and the second resistor each comprises a metal material, the metal material that the first resistor comprises and the metal material that the second resistor comprises being substantially the same as each other.

2. The overcurrent protection integrated circuit according to claim 1, wherein the metal material that the first resistor comprises and the metal material that the second resistor comprises comprise aluminum, or aluminum-based alloy.

3. The overcurrent protection integrated circuit according to claim 1, wherein
the overcurrent protection integrated circuit comprises a semiconductor chip comprising a stack of multiple semiconductor circuit formation layers,
the first resistor and the second resistor are arranged in respective different ones of the semiconductor circuit formation layers, and
the first resistor and the second resistor are positioned to overlap each other vertically in a thickness direction of the semiconductor circuit formation layers.

4. The overcurrent protection integrated circuit according to claim 1, wherein
the overcurrent protection integrated circuit comprises a semiconductor chip comprising a stack of multiple semiconductor circuit formation layers,
the first resistor and the second resistor are arranged in respective different ones of the semiconductor circuit formation layers, and
the first resistor and the second resistor are positioned close to each other in a direction along a plane of the semiconductor circuit formation layers.

5. The overcurrent protection integrated circuit according to claim 1, wherein the second resistor has a linear shape.

6. The overcurrent protection integrated circuit according to claim 3, wherein the second resistor is arranged only in one of the semiconductor circuit formation layers.

7. The overcurrent protection integrated circuit according to claim 4, wherein the second resistor is arranged only in one of the semiconductor circuit formation layers.

8. The overcurrent protection integrated circuit according to claim 1, wherein
the second resistor is elongated in a longitudinal direction,
the overcurrent protection integrated circuit further comprises a metal wiring arranged in a vicinity of a side part, of the second resistor, extending along the longitudinal direction, the metal wiring having a linear shape and comprising a metal material same as the metal material that the second resistor comprises, and
the metal wiring comprises a dummy pattern.
